(19) United States
(12) Patent Application Publication
(10) Pub. No.: US 2023/0411563 A1
(43) Pub. Date: Dec. 21, 2023

(54) Ultra-Thin Fin LED Device And Ink Composition Comprising The Same

(71) Applicant: Kookmin University Industry Academy Cooperation Foundation, Seoul (KR)

(72) Inventor: Young Rag DO, Seoul (KR)

(21) Appl. No.: 18/212,139

(22) Filed: Jun. 20, 2023

(30) Foreign Application Priority Data
Jun. 21, 2022 (KR) 10-2022-0075384

(51) Int. Cl. H01L 33/44; H01L 33/20

(52) U.S. Cl. CPC H01L 33/44; H01L 33/20

(57) ABSTRACT

The present invention relates to an LED device, and more particularly, to an ultra-thin pin LED device and an ink composition including the same. According to the present invention, it is advantageous to achieve higher luminance and light efficiency by increasing the emission area and preventing or minimizing the reduction in efficiency due to surface defects. In addition, it is very suitable for a dielectrophoretic method of self-aligning the devices on electrodes by electric field, and the drivable mounting efficiency can be increased by ensuring that the surface in contact with the electrodes is a surface other than the side surfaces.

### CROSS-REFERENCE TO RELATED APPLICATIONS

This application claims the benefit and priority of Korean Patent Application No. 10-2022-0075384 filed Jun. 21, 2022. The entire disclosure of the above application is incorporated herein by reference.

### BACKGROUND OF THE INVENTION

### Technical Field

The present invention relates to an LED device, and more particularly, to an ultra-thin pin LED device and an ink composition including the same.

### Discussion

Micro-LEDs and nano-LEDs can implement an excellent feeling of color and high efficiency and are eco-friendly materials, thereby being used as core materials for displays. In line with such market conditions, recently, research is being conducted to develop a new nanorod LED structure or a nanocable LED having a shell coated by a new manufacturing process. In addition, research on a protective film material to achieve high efficiency and high stability of a protective film covering an outer surface of nanorods, and research and development on a ligand material that is advantageous for a subsequent process are also being conducted.

In line with these researches in the material fields, large-sized red, green, and blue micro-LED display TVs have recently been commercialized, and in the future, TVs, which implement full-color through blue subpixels implemented using blue micro-LEDs or nano-LEDs and red and green subpixels implemented by emitting quantum dots through the blue LEDs, are expected to be commercialized. In addition, red, green, and blue nano-LED display TVs will also be commercialized.

The micro-LED displays have advantages of high performance characteristics, very long theoretical lifetime, and very high efficiency, but when developed as displays with 8K resolution, a red micro-LED, a green micro-LED, and a blue micro-LED should correspond one-to-one to each of nearly 100 million subpixels. Thus, with pick and place technology for manufacturing micro-LED displays, it is difficult to manufacture true high-resolution commercial displays ranging from smartphones to TVs due to the limitations of process technology in view of high unit price, high process defect rate, and low productivity. In addition, it is more difficult to individually arrange nano-LEDs on subpixels using the pick and place technology for micro-LEDs.

In order to overcome these difficulties, Korean Patent Registration No. 10-1436123 discloses a display manufactured through a method of dropping a solution mixed with nanorod-type LEDs on subpixels and then forming an electric field between two alignment electrodes to self-align nanorod-type LED devices on the electrodes, thereby forming the subpixels. However, in the used nanorod-type LED devices, since a major axis of the LED device coincides with a stack direction of the layers constituting the device, that is, a stack direction of each layer in a p-GaN/InGaN multi-quantum well (MQW)/n-GaN stacked structure, an emission area is narrow. In addition, when manufacturing a nanorod-type LED device by etching a commercially available wafer, it is necessary to etch the wafer as much as the length of the major axis, so surface defects are highly likely to occur as a lot of etchings is performed. Further, since the emission area is narrow, surface defects have a relatively large effect on the degradation in efficiency. In addition, since it is difficult to optimize the electron-hole recombination rate, there is a problem that the luminous efficiency is significantly lower than that of an original wafer. Accordingly, there is a problem in that a large number of LEDs must be mounted in order for an apparatus to which such a nanorod-type LED device is mounted to express a desired level of luminous efficiency.

Therefore, in order to solve these problems, a structural change may be considered so that the major axis of the rod-type LED device is perpendicular to the stacking direction of each layer. In this case, the major axis should be the length and/or width of the LED device, and the thickness of the device becomes thinner compared to the length or width. Thus, the possibility of surface defects is low due to the shallow etching depth when the wafer is etched, but after etching, the area of the lower surface of the etched LED pillar connected to the wafer is large, so it is not easy to separate the etched LED pillar. In addition, it may be difficult to obtain an LED device having a desired size and efficiency because the separated LED device cannot be completely separated during separation. In addition, in the case of a rod-type LED device in which the stacking directions of the n-type semiconductor layer and p-type semiconductor layer are perpendicular to the major axis of the device, when the LED device is mounted on an electrode through dielectrophoresis by applying an electric field, the surface of the p-type semiconductor layer or n-type semiconductor layer must be self-aligned to be placed on the electrode. When the side surface of the device is self-aligned so as to be in contact with the electrode, there is a problem in that an electric short occurs when driving power is applied, and light is not emitted. Further, even when self-aligned so that the surface of the p-type semiconductor layer or the n-type semiconductor layer of the LED device, rather than the side surface, is placed on the electrode, the p-type semiconductor layer or the n-type semiconductor layer is random, or any one of these layers is only mounted to contact slightly more on the electrode, whereby there is a limit to implementing a light source for an LED electrode assembly using DC power as a driving power source, a display including the same, or the like.

### DISCLOSURE

### Technical Problem

The present invention has been devised to solve the above-mentioned problems, and an aspect of the present invention is to provide an ultra-thin fin LED device which can increase an emission area while reducing the thickness of a photoactive layer exposed to a surface to prevent a degradation in efficiency due to surface defect, maintain high efficiency in light extraction efficiency and further improves luminance by minimizing a decrease in electron-hole recombination efficiency due to non-uniformity of electron and hole velocities and the resulting decrease in luminous efficiency, and at the same time increase the drivable mounting efficiency by minimizing side contact during self-alignment on the mounting electrode through dielectrophoresis, and an ink composition including the same.

In addition, another aspect of the present invention is to provide an ultra-thin pin LED device, which is capable of increasing drivable mounting efficiency while allowing a specific surface to selectively contact a mounting electrode, thereby extending the range of selection of power sources used in light sources for LED electrode assemblies, displays or the like implemented using the same to DC power supplies, and can achieve higher luminous efficiency, and an ink composition including the same.

### SUMMARY

The present invention has been researched under support of National Research and Development Project, and specific information of National Research and Development Project is as follow:
[Project Series Number] 1415174040
[Project Number] 20016290
[Government Department Name] Ministry of Trade, Industry and Energy
[Project Management Authority Name] Korea Evaluation Institute of Industrial Technology
[Research Program Name] Electronic Components Industry Technology Development-Super Large Micro-LED Modular Display
[Research Project Name] Development of sub-micron blue light-emitting source technology for modular display
[Project Execution Organization Name] Kookmin University Industry Academic Cooperation Foundation
[Period of Research] Apr. 1, 2021 to Dec. 31, 2024
[Project Series Number] 1711130702
[Project Number] 2021R1A2C2009521
[Government Department Name] Ministry of Science and ICT
[Project Management Authority Name] Korea Evaluation Institute of Industrial Technology
[Research Program Name] Middle-level Researcher Support Project
[Research Project Name] Development of dot-LED material and display source/application technology
[Contribution Ratio]
[Project Execution Organization Name] Kookmin University Industry Academic Cooperation Foundation
[Period of Research] Mar. 1, 2021 to Feb. 28, 2022
[Project Series Number] 1711105790
[Project Number] 2016R1A5A1012966
[Government Department Name] Ministry of Science and ICT
[Project Management Authority Name] National Research Foundation of Korea
[Research Program Name] Science and Engineering Research Center (S/ERC)
[Research Project Name] Circadian ICT research center using hybrid device
[Project Execution Organization Name] Kookmin University Industry Academic Cooperation Foundation
[Period of Research] Jan. 1, to Dec. 31, 2021

### Technical Solution

In order to solve the above aspects, the present invention provides an ultra-thin pin LED device, including: a plurality of layers, and based on mutually perpendicular x-axis, y-axis and z-axis wherein the x-axis direction is a major axis and the layers are stacked in the z-axis direction, a first surface and a second surface opposite to each other in the z-axis direction, and other side surfaces, wherein as the device in a solvent is attracted by dielectrophoretic force toward a mounting electrode where power is applied and an electric field is formed, the first or second surfaces among the various surfaces of the device are configured to contact an upper surface of the mounting electrode more dominantly than the side surfaces.

According to an embodiment of the present invention, the device may be configured such that a drivable mounting ratio in which the first surface or the second surface of each element is independently mounted to come into contact with the upper surface of the mounting electrode satisfies 55% or more based on 120 devices under 10 kHz and 40 Vpp power conditions.

In addition, the device may be configured such that a selective mounting ratio in which any one surface selected from the first and second surfaces is mounted to come into contact with the upper surface of the mounting electrode satisfies 70% or more based on 120 devices under 10 kHz and 40 Vpp power conditions.

In addition, the lowermost layer having the first surface may have a structure containing a plurality of pores in a region ranging from the first surface to a predetermined thickness.

In addition, the lowermost layer having the first surface and the uppermost layer having the second surface may be made of materials different from each other in at least one of electrical conductivity and dielectric constant, more preferably, the uppermost layer having the second surface may have a higher electrical conductivity than that of the lowermost layer having the first surface, even more preferably, the electrical conductivity of the uppermost layer may be 10 times or more than that of the lowermost layer, and still more preferably the electrical conductivity of the uppermost layer may be 100 times or more than that of the lowermost layer.

In addition, in order to generate rotational torque based on an imaginary rotation axis passing through the center of the device in the x-axis direction under an electric field, the device may further include a rotation induction film surrounding the side surface of the device.

In addition, the rotation induction film may have a real part of a K(ω) value according to Equation 1 below that satisfies more than 0 and up to 0.72, and more preferably more than and up to 0.62 in at least a part of frequency range within a frequency range of 10 GHz or less.

$$K ( ω ) = \frac{{ε}_{p}^{*} - {ε}_{m}^{*}}{{ε}_{p}^{*} + 2 {ε}_{m}^{*}} \qquad [ Equation 1 ]$$

In Equation 1, K(ω) is an equation between εₚ*, the complex permittivity of the spherical core-shell particle composed of GaN as a core part and a rotation induction film as a shell part, and εₘ*, the complex permittivity of the solvent at an angular frequency ω, wherein the εp* is according to Equation 2 below:

$${ε}_{p}^{*} = {ε}_{2}^{*} \frac{{( \frac{{R}_{2}}{{R}_{1}} )}^{3} + 2 ( \frac{{ε}_{1}^{*} - {ε}_{2}^{*}}{{ε}_{1}^{*} + 2 {ε}_{2}^{*}} )}{{( \frac{{R}_{2}}{{R}_{1}} )}^{3} - ( \frac{{ε}_{1}^{*} - {ε}_{2}^{*}}{{ε}_{1}^{*} + 2 {ε}_{2}^{*}} )} \qquad [ Equation 2 ]$$

In Equation 2, R₁ is a radius of the core part, R₂ is a radius of the core-shell particle, and ε₁* and ε₂* are the complex permittivity of the core part and the shell part, respectively.

In addition, the plurality of layers may include an n-type conductive semiconductor layer, a photoactive layer, and a p-type conductive semiconductor layer.

In addition, the ultra-thin pin LED device may have a thickness, a distance in the z-axis direction, of 0.1 to 3 μm and a length in the x-axis direction of 1 to 10 μm.

Further, the width of the ultra-thin pin LED device, which is the length in the y-axis direction, may be smaller than the thickness, which is the length in the z-axis direction.

In addition, the present invention provides an ink composition comprising a plurality of ultra-thin pin LED devices according to the present invention, and a solvent.

Hereinafter, terms used in the present invention will be defined.

In the description of the embodiments according to the present invention, when each layer, region, pattern or structure is described as being formed “on”, “above”, “upper”, “under”, “lower” or “below” another substrate, layer, region, or pattern, the meaning of the terms “on”, “above”, “over”, “under”, “below”, or “beneath includes both cases of “directly” and “indirectly”.

### Advantageous Effects

The ultra-thin pin LED device according to the present invention is advantageous in achieving high luminance and light efficiency by increasing an emission area compared to a conventional rod-type LED device. In addition, by greatly reducing the area of the photoactive layer exposed to the surface while increasing the emission area, reduction in efficiency due to surface defects can be prevented or minimized. Furthermore, it is very suitable for a method of self-aligning devices on electrodes with dielectrophoretic force by electric field, and further, the drivable mounting efficiency can be increased by ensuring that the surface in contact with the electrode after self-alignment is the uppermost or lowermost surface instead of the side surfaces. In addition, by minimizing side contact while allowing a specific surface of the uppermost and lowermost surfaces to selectively contact the mounting electrode, the range of selection of power sources used in light sources for LED electrode assemblies, displays or the like implemented using the same can be extended to DC power, and higher luminance can be achieved. Thus, it can be widely applied as a material for displays and various light sources.

### DESCRIPTION OF DRAWINGS

FIGS. 1 and 2 are a perspective view of an ultra-thin fin LED device according to an embodiment of the present invention and a cross-sectional view taken along line X-X′, respectively.

FIGS. 3 and 4 are cross-sectional views perpendicular to a longitudinal direction of ultra-thin fin LED devices according to various embodiments of the present invention.

FIG. 5 is a schematic diagram of a mounting form that may appear when a rod-type element in which several layers are stacked in the thickness direction and a major axis in the longitudinal direction is perpendicular to the thickness direction is mounted on a mounting electrode.

FIGS. 6 and 7 are graphs showing a real part of the value according to Equation 1 for each frequency of an electric field formed when a single particle formed of each of the materials shown is placed in a medium of acetone and isopropyl alcohol, respectively.

FIGS. 8A to 8D are graphs showing a real part of the value according to Equation 1 for each frequency of an electric field formed when a spherical core-shell particle in which a rotation induction film is formed with each of shown materials to have a thickness of 30 nm on a surface of a GaN core having a radius of 400 nm is placed in solvents having different permittivity of 10, 15, 20.7, and 28, respectively.

FIGS. 9 and 10 are diagrams schematically illustrating a motion of an ultra-thin pin LED device placed in a medium above a mounting electrode where an electric field is formed when it is mounted on the mounting electrode through dielectrophoretic force, wherein FIG. 9 is a diagram schematically illustrating a motion in which an ultra-thin pin LED device is drawn to two adjacent mounting electrode surfaces, and FIG. 10 is a diagram schematically illustrating a rotation torque generated in an ultra-thin pin LED device based on an x-axis which is a major axis thereof.

FIG. 11 is a scanning electron microscope (SEM) photograph of various mounting forms that appear after an ultra-thin pin LED device according to an embodiment of the present invention is mounted on a mounting electrode through dielectrophoresis.

FIG. 12 is a schematic cross-sectional view in which an ultra-thin pin LED device according to an embodiment of the present invention implements an LED electrode assembly.

FIGS. 13 to 16 are side SEM photographs of ultra-thin pin LED devices according to various embodiments of the present invention.

FIG. 17 is a SEM photograph of a part of an area where an ultra-thin pin LED device is mounted, taken as an experimental result of Experimental Example 1 for an ultra-thin pin LED device according to Example 1.

### DESCRIPTION OF THE PREFERRED EMBODIMENTS OF THE INVENTION

Hereinafter, embodiments of the present invention will be described in detail with reference to the accompanying drawings so that the present invention can be easily implemented by one of ordinary skill in the art to which the present invention pertains. The present invention may be embodied in a variety of forms and is not limited to the embodiments described herein.

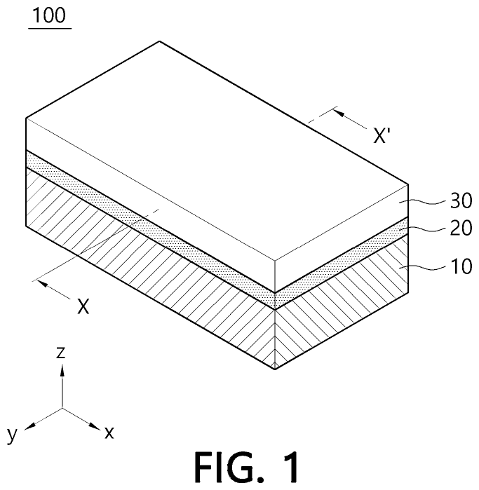

Referring to FIGS. 1 to 4, an ultra-thin pin LED devices 100, 101 and 102 according to an embodiment of the present invention has, based on mutually perpendicular x-axis, y-axis and z-axis wherein layers 10, 20, 30, 40, and 60 are stacked in the z-axis direction, a first surface (B) and a second surface (T) opposite to each other in the z-axis direction, and other side surfaces (S), wherein the x-axis has the longest length and thus becomes a major axis of the ultra-thin pin LED devices 100, 101 and 102.

These rod-type LED devices can be self-aligned on a mounting electrode through dielectrophoretic force within an electric field formed by the power applied to the mounting electrode, wherein both ends of the x-axis, a major axis of the rod-type LED device, are generally disposed to contact upper surfaces of two mutually spaced mounting electrodes to which power is applied.

In this case, when several layers constituting the device are stacked in the x-axis direction, which is the major axis of the rod-type LED device, one end of the rod-type LED device in the direction of the major axis becomes one conductive semiconductor layer or a layer adjacent thereto, and the other end in the direction of the major axis becomes another conductive semiconductor layer or a layer adjacent thereto. When these rod-type LED devices are mounted on mounting electrodes spaced apart from each other through dielectrophoretic force, it is mounted so that one end of the rod-type LED device in the direction of the major axis is in contact with one mounting electrode, and the other end in the major axis direction is in contact with another spaced apart mounting electrode. Therefore, there is no case where the mounted rod-type LED device is not driven. In addition, in the case of a rod-type LED device having such a laminated structure, even if the shape is a polyhedron, for example, a rectangular parallelepiped, any of the side surfaces whose plane direction is parallel to the major axis direction can be driven even in contact with the mounting electrode.

However, as shown in FIGS. 1 to 4, the layers 10, 20, 30, 40 and 60 constituting the LED devices 100, 101 and 102 are stacked in the z-axis direction perpendicular to the x-axis direction, which is the major axis direction of the device, there is a limitation that driving is possible only when a specific surface among the side surfaces of the device based on the x-axis direction, which is the major axis, is in contact with the mounting electrode.

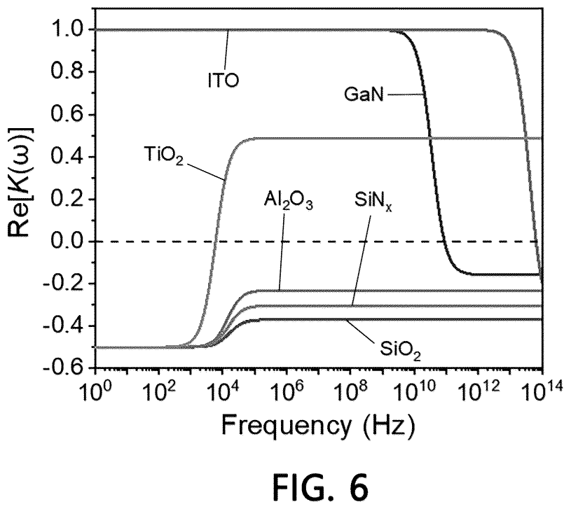

Specifically, referring to FIG. 5, the ends of the LED device 3 in the major axis direction are self-aligned to be in contact with each of the two adjacent mounting electrodes 1 and 2 through dielectrophoresis. As the stacking direction of the layers 4, 5 and 6 constituting the LED device becomes perpendicular to the major axis direction, the mounting form of the LED device 3 mounted on the two mounting electrodes 1 and 2 is divided into a case where the surface of the first conductive semiconductor layer 4 or the surface of the second conductive semiconductor layer 6 facing in the thickness direction of the LED device 3 is in contact with the surfaces of the two mounting electrodes 1 and 2, and a case the remaining side surfaces of the LED device 3 except for these two surfaces are in contact with the two mounting electrodes 1 and 2. Among these mounting forms, when the other side surfaces of the LED device 3 are mounted so as to contact the two mounting electrodes 1 and 2, all of the first conductive semiconductor layer 4, the photoactive layer 5 and the second conductive semiconductor layer 6 come into contact with one electrode, whereby the LED device mounted in this form does not emit light even when driving power is applied to the mounting electrodes 1 and 2, and causes an electrical short.

The ultra-thin pin LED devices 100, 101 and 102 have a first surface (B) and a second surface (T), and other side surfaces (S) based on mutually perpendicular x-axis, y-axis and z-axis wherein the first surface (B) and second surface (T) are opposite to each other in the z-axis direction in which the layers 10, 20, 30, 40 and 60 are stacked, and wherein the length in the x-axis direction is longer than the thickness in the z-axis direction. Therefore, in the case of these ultra-thin pin LED devices 100, 101 and 102, in order to be driven, that is, to emit light after being mounted on two mounting electrodes by dielectrophoresis, it is necessary to mount the ultra-thin pin LED devices 100, 101 and 102 such that the first surface (B) or the second surface (T) among the various surfaces constituting the LED devices 100, 101 and 102 are in contact with the mounting electrodes.

Accordingly, the present inventors have continuously studied a method of self-aligning the ultra-thin pin LED devices 100, 101 and 102 on mounting electrodes using an electric field formed by two mounting electrodes spaced apart from each other in the x-axis direction, which is a major axis, and further a method of dielectrophoresis such that the first surface (B) or the second surface (T) among the various surfaces of the device can be in contact with the mounting electrodes. As a result, the present inventors have found that through the design of the material, structure and the like of the layers constituting the LED device, the dielectrophoresis can be performed so that the first surface (B) or the second surface (T) of the device is in contact with the upper surface of the mounting electrodes more dominantly than the side surfaces (S), and have reached the present invention.

Specifically, the movement of particles in a medium during dielectrophoresis can be explained through a dielectrophoresis mechanism, wherein the dielectrophoresis refers to a phenomenon in which a directional force is applied to a particle by a dipole induced in the particle when the particle is placed in a non-uniform electric field. Here, the strength of the force may vary depending on the electrical characteristics of the particles and the medium, the dielectric characteristics, the frequency of the alternating electric field, etc., and the time average force (F DEP) applied to the particles during the dielectrophoresis is shown in Equation 3 below.

F_{DEP}=2πr³εₘ Re[K(ω)]∇|E|² [Equation 3]

In Equation 3, r, εₘ, and E represent the radius of the particle, the permittivity of the medium, and the magnitude of the mean square root of the applied alternating current electric field, respectively. In addition, Re[K(ω)] is a factor that determines the direction in which the near-spherical particles move, and means a real part of the value according to Equation 1 below.

$$K ( ω ) = \frac{{ε}_{p}^{*} - {ε}_{m}^{*}}{{ε}_{p}^{*} + 2 {ε}_{m}^{*}} \qquad [ Equation 1 ]$$

Here, εₚ* and εₘ* are the complex permittivity of the particle and the medium, respectively, and ε* is determined by Equation 4 below.

$${ε}^{*} = ε - j \frac{σ}{ω} \qquad [ Equation 4 ]$$

Here, σ refers to an electrical conductivity coefficient, ε refers to a dielectric constant, ω refers to an angular frequency (ω=2πf), and j refers to an imaginary part (j=\sqrt{−1}).

The movement of the particles during dielectrophoresis greatly depends on the change of the factor according to Equation 1. In other words, the sign changes according to the frequency of Re[K(ω)] is the most important factor in determining the direction for the phenomenon in which particles move toward or away from a high electric field region. In this case, if Re[K(ω)] has a positive value, the particles move toward a high electric field region, which is called positive dielectrophoresis (pDEP), whereas if Re[K(ω)] has a negative value, the particles move away from the high electric field region, which is called negative dielectrophoresis (nDEP).

The ultra-thin pin LED device is subjected to dielectrophoretic force while being dispersed in a solvent as a medium. Table 1 below shows the electrical conductivity and dielectric constant for each kind of materials that may be included in the solvent and the ultra-thin pin LED device.

TABLE 1

| | Solvent | | Materials that may be provided in the LED device | | | | | |
|---|---|---|---|---|---|---|---|---|
| | Acetone | IPA | GaN | ITO | SiO₂ | SiNₓ | Al₂O₃ | TiO₂ |
| Dielectric constant | 20.7 | 18.6 | 12.2 | 3.2 | 3.9 | 6.2 | 9.0 | 80 |
| (ε) | | | | | | | | |
| Electrical | 20 × 10⁻⁶ | 6 × 10⁻⁶ | 104 | 10⁵ | 1 × 10⁻¹⁰ | 2 × 10⁻¹³ | 1 × 10⁻¹⁴ | 1 × 10⁻¹³ |
| conductivity ( σ; S/m) | | | | | | | | |

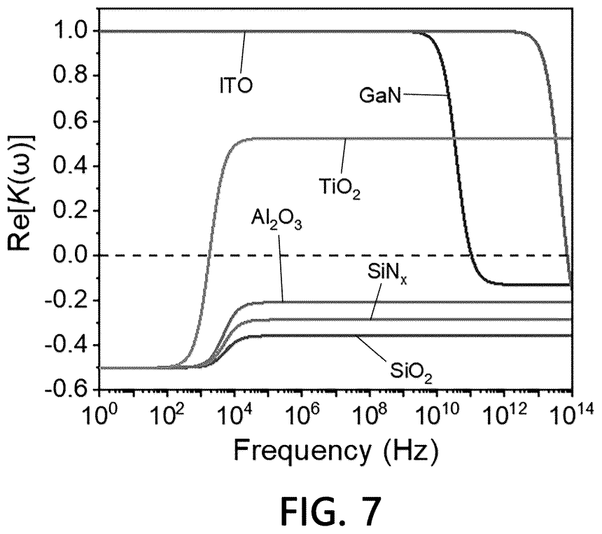

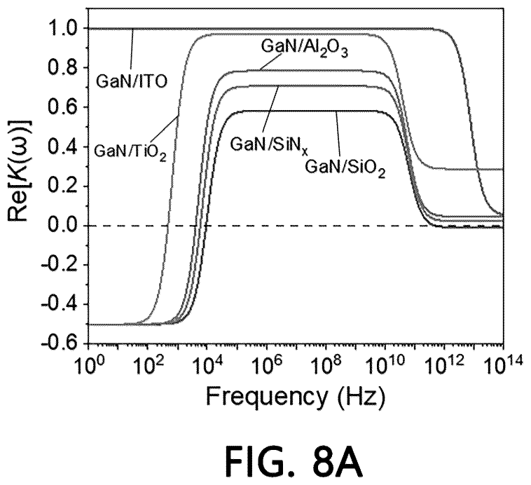

In addition, referring to FIGS. 6 and 7, assuming that a single particle is a material that can be included in the ultra-thin pin LED device placed in acetone and isopropyl alcohol (IPA), respectively, as examples of the solvent, the frequency dependence of Re[K(ω)] has a positive dielectrophoretic (pDEP) value in a broad frequency range in the case of ITO and GaN, whereas on the contrary, in the case of TiO₂, it has a negative value at low frequencies and a positive value at high frequencies. In addition, particles of materials such as SiO₂, SiNₓ, and Al₂O have a negative dielectrophoretic (nDEP) value regardless of frequency. Therefore, GaN particles, ITO particles or TiO₂ particles have a directivity toward or away from a strong electric field depending on the frequency. In addition, particles of materials such as SiO₂, SiNₓ and Al₂O always move away from the strong electric field regardless of the type of medium such as acetone and IPA and the frequency of the applied power.

Therefore, the dielectrophoretic force received by the ultra-thin pin LED device is also determined by the dielectric constant and electrical conductivity of the materials constituting the ultra-thin pin LED device and the solvent as the medium in which the ultra-thin pin LED device is placed, and the frequency of the applied electric field, whereby the sign (positive/negative) and level of the value of Re[K(ω)] acting on each surface of the ultra-thin pin LED device can be adjusted to control the movement so that the desired surface is selectively placed on the mounting electrodes. However, since the ultra-thin pin LED device is not a single device made of one material, it is almost impossible to predict the movement of the ultra-thin pin LED device in which layers of various materials are stacked by using the experimental results of FIGS. 6 and 7. Accordingly, assuming that the spherical particles are not particles of a single material, but core-shell structured particles having different electrical conductivity and dielectric constant for each layer, and considering that the particle in Equation 1 is the core-shell structured particle, the present inventors have calculated the complex permittivity of the core-shell structured particles through Equation 2 below to calculate the value of Equation 1, thereby examining the dielectrophoretic force and moving direction for each dielectric constant of a solvent as a medium and frequency of applied power.

$${ε}_{p}^{*} = {ε}_{2}^{*} \frac{{( \frac{{R}_{2}}{{R}_{1}} )}^{3} + 2 ( \frac{{ε}_{1}^{*} - {ε}_{2}^{*}}{{ε}_{1}^{*} + 2 {ε}_{2}^{*}} )}{{( \frac{{R}_{2}}{{R}_{1}} )}^{3} - ( \frac{{ε}_{1}^{*} - {ε}_{2}^{*}}{{ε}_{1}^{*} + 2 {ε}_{2}^{*}} )} \qquad [ Equation 2 ]$$

In Equation 2, R₁ is a radius of the core part, R₂ is a radius of the core-shell particle, and ε₁* and ε₂* are the complex permittivity of the core part and the shell part, respectively.

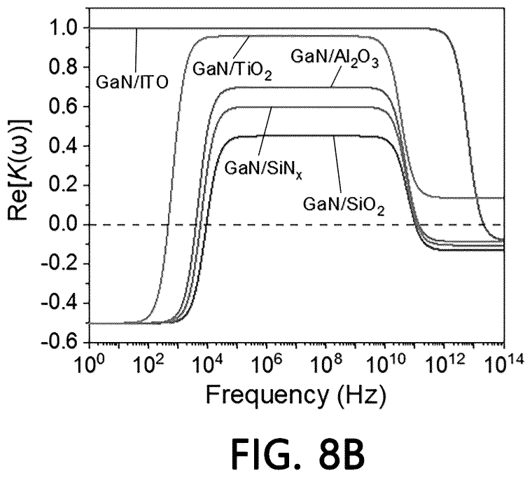

Referring to FIGS. 8A to 8D, FIGS. 8A to 8D show a real part of the value according to Equation 1 for each dielectric constant of the solvent and frequency of the applied power with respect to a spherical core-shell particle with a radius of 430 nm in which the core part is fixed to GaN having a radius of 400 nm and the shell part is changed to ITO, SiO₂, SiNₓ, Al₂O₃, and TiO₂ each having a thickness of 30 nm. Specifically, as confirmed in FIGS. 6 and 7, each of GaN and ITO has a positive dielectrophoretic (pDEP) value close to 1 even in a fairly large high frequency band in the case of a single particle, whereas FIGS. 8A to 8D show that even in the case of particles having a core-shell structure in which ITO is disposed as a shell part in GaN as a core part, it still has a large positive dielectrophoretic (pDEP) value close to 1. In addition, it can be seen that in the case of core-shell structured particles in which TiO₂ is disposed as a shell part in GaN as a core part, TiO₂ is affected by GaN having a large positive dielectrophoretic value when being a single particle, and thus, has a larger positive dielectrophoretic (pDEP) value than when being a single particle, but the frequency band having a positive dielectrophoretic (pDEP) value is reduced compared to the case of TiO₂ single particle. On the other hand, in the case of SiO₂, SiNₓ and Al₂O₃, each of which had a negative dielectrophoretic (nDEP) value in a single particle, they are influenced by the large positive dielectrophoretic (pDEP) value of GaN disposed as a shell in core-shell structured particles having a core part that is GaN, and thus, change to have a positive dielectrophoretic (pDEP) value in some frequency regions of the frequency range that causes GaN to have a positive dielectrophoretic (pDEP) value, more preferably a positive dielectrophoretic (pDEP) value of 1.0, for example, a frequency range of 10 GHz or less. Taking these results together, therefore, when a certain material layer is provided as the outermost layer in a Group III-nitride compound, for example, a GaN LED device, a frequency band having a positive dielectrophoretic (pDEP) value is obtained, although there is a difference in size.

Through these results, when materially and/or structurally adjusting the electrical conductivity and dielectric constant characteristics of the layers (or surfaces) constituting the ultra-thin pin LED device, it is possible to implement a mounting form in which the ultra-thin pin LED device is led toward the mounting electrode at a predetermined frequency, and further the first surface (B) or the second surface (T) of the device is led toward and contacts the upper surface of the mounting electrode more dominantly than the side surfaces, whereby it is possible to increase the drivable mounting ratio and achieve increased luminance. In addition, electrical short circuit and leakage caused by the side surface of the ultra-thin pin LED device contacting the mounting electrode can be minimized.

Meanwhile, in the present invention, the term ‘dominantly’ means that for example, when 120 substantially identical devices are self-aligned through dielectrophoretic force, the number of devices mounted so that the first surface (B) or the second surface (T), rather than the side surface (S), of each element independently comes into contact with the upper surface of the mounting electrode exceeds 50% of the total number of input devices, and in another example, the number ratio is 55%, 60%, 65%, or 70% or more.

In addition, a device mounted so that the first surface (B) or the second surface (T), rather than the side surfaces (S), of the device comes into contact with the upper surface of the mounting electrode when self-aligned through dielectrophoresis can be classified as a drivable device capable of emitting light by a driving power applied to the mounting electrode and a driving electrode formed to electrically contact the opposite surface facing the mounting surface, which is the first surface (B) or the second surface (T). In the present invention, the ratio of the number of devices mounted in a drivable form among the total number of LED devices mounted on the mounting electrode is defined as a drivable mounting ratio. For example, when the total number of ultra-thin pin LED devices mounted on the upper surface of the mounting electrode is L, and among them, the number of ultra-thin pin LED devices mounted so that the first surface (B) is in contact with the upper surface of the mounting electrode is M, and the number of ultra-thin pin LED devices mounted such that the second surface (T) is in contact with the upper surface of the mounting electrode is N, the drivable mounting ratio is calculated by the formula [(M+N)/L]×100.

According to an embodiment of the present invention, the device can have a drivable mounting ratio in which the first surface or the second surface of each element is independently mounted so as to come into contact with the upper surface of the mounting electrode, which satisfies 55% or more, preferably 70% or more, more preferably 75% or more, still more preferably 80% or more, 90% or more, or 95% or more based on 120 devices under 10 kHz and 40 Vpp power conditions, whereby excellent luminance can be achieved by minimizing the case where the input ultra-thin pin LED devices are not mounted or the side surface is mounted, and the manufacturing cost can be lowered by reducing the number of wasted ultra-thin pin LED devices.

In addition, according to an embodiment of the present invention, a plurality of the substantially identical devices may be mounted such that only any one of the first surface (B) and second surface (T) of the device is selectively directed toward the mounting electrode and is in contact with the upper surface of the mounting electrode. In this regard, in the present invention, the ratio of the number of devices that are mounted so that only any one of the first surface (B) and the second surface (T) of the device is selectively in contact with the upper surface of the mounting electrode and emit light even when DC power is applied to the driving electrode, among the total number of devices mounted on the mounting electrode, is defined as a selective mounting ratio. For example, when the total number of ultra-thin pin LED devices mounted on the upper surface of the mounting electrode is L, and among them, the number of ultra-thin pin LED devices mounted so that the first surface (B) is in contact with the upper surface of the mounting electrode is M, and the number of ultra-thin pin LED devices mounted such that the second surface (T) is in contact with the upper surface of the mounting electrode is N, the selective mounting ratio refers to the larger of the ratios calculated by the formulas [M/L]×100 and [N/L]×100.

The ultra-thin pin LED device according to an embodiment of the present invention may be configured such that the selective mounting ratio in which only any one of the first surface (B) and second surface (T) is mounted to come into contact with the upper surface of the mounting electrode satisfies 70% or more, more preferably 85% or more, even more preferably 90% or more, and even more preferably 93% or more based on 120 devices under kHz and 40 Vpp power conditions. Thereby, it is possible to increase the driving rate and luminance of the mounted ultra-thin pin LED devices, and in particular, when the contact ratio of a specific surface is increased, the range of applications that can select DC power instead of AC as the driving power source can be expanded. Further, it may be advantageous to implement increased luminance due to the use of DC power.

Before describing the ultra-thin pin LED device configured so that the first surface (B) or the second surface (T) of the various surfaces of the device as described above is dominantly attracted to and contacted with the upper surface of the mounting electrode, a plurality of essential layers constituting the ultra-thin pin LED device will be described first.

Specifically, the ultra-thin fin LED device 100 includes a conductive semiconductor layer, and as the conductive semiconductor layer, any conductive semiconductor layer employed in a conventional LED device used for lighting, display, and the like may be used without limitation. According to a preferred embodiment of the present invention, the ultra-thin fin LED device 100 may include a first conductive semiconductor layer 10 and a second conductive semiconductor layer 30, wherein any one of the first conductive semiconductor layer 10 and the second conductive semiconductor layer 30 may include at least one n-type semiconductor layer, and the other conductive semiconductor layer may include at least one p-type semiconductor layer.

When the first conductive semiconductor layer 10 includes an n-type semiconductor layer, the n-type semiconductor layer may be at least one selected from semiconductor materials having an empirical formula of InₓAl_{y}Ga_{1-x-y}N(0≤x≤1, 0≤y≤1, 0≤x+y≤1), for example, InAlGaN, GaN, AlGaN, InGaN, AlN, InN, and the like, and may be doped with a first conductive dopant (e.g., Si, Ge, Sn, etc.). According to a preferred embodiment of the present invention, the thickness of the first conductive semiconductor layer 10 including an n-type semiconductor layer may be 0.2 to 3 μm, but is not limited thereto.

When the second conductive semiconductor layer 30 includes an p-type semiconductor layer, the p-type semiconductor layer may be at least one selected from semiconductor materials having an empirical formula of InₓAl_{y}Ga_{1-x-y}N(0≤x≤1, 0≤y≤1, 0≤x+y≤1), for example, InAlGaN, GaN, AlGaN, InGaN, AlN, InN, and the like, and may be doped with a second conductive dopant (e.g., Mg). According to a preferred embodiment of the present invention, the thickness of the second conductive semiconductor layer 30 including an p-type semiconductor layer may be 0.01 to 0.35 μm, but is not limited thereto.

Next, the ultra-thin fin LED device 100 may include a photoactive layer 20, wherein the photoactive layer 20 may be formed between the first conductive semiconductor layer and the second conductive semiconductor layer 30, and may be formed in a single or multiple quantum well structure. As the photoactive layer 20, any photoactive layer included in a conventional LED device used for lighting, display, etc. may be used without limitation. A clad layer (not shown) doped with a conductive dopant may be formed above and/or below the photoactive layer 2, wherein the clad layer doped with a conductive dopant may be implemented as an AlGaN layer or an InAlGaN layer. In addition, materials such as AlGaN and AlInGaN may also be used as the photoactive layer 20. In the photoactive layer 20, when an electric field is applied to the device, electrons and holes respectively moving from the conductive semiconductor layers positioned above and below the photoactive layer to the photoactive layer are coupled to generate electron-hole pairs in the photoactive layer, thereby emitting light. According to a preferred embodiment of the present invention, the photoactive layer 20 may have a thickness of 30 to 300 nm, but is not limited thereto.

In addition, the ultra-thin fin LED device 100 is illustrated as including the first conductive semiconductor layer 10, the photoactive layer 20, and the second conductive photoactive layer 30 as minimum components, but may further other active layers, conductive semiconductor layers, phosphor layers, hole blocking layers, and/or electrode layers above/below each of the above layers.

Meanwhile, the ultra-thin pin LED device having the plurality of layers 10, 20 and 30 stacked therein as described above may be configured to have a different material and/or structure depending on a position in the device so that the first surface (B) or the second surface (T) among the various surfaces of the device as described above can be dominantly attracted to and contacted with the upper surface of the mounting electrode, and further the drivably mounted ratio and selective mounting ratio can be increased.

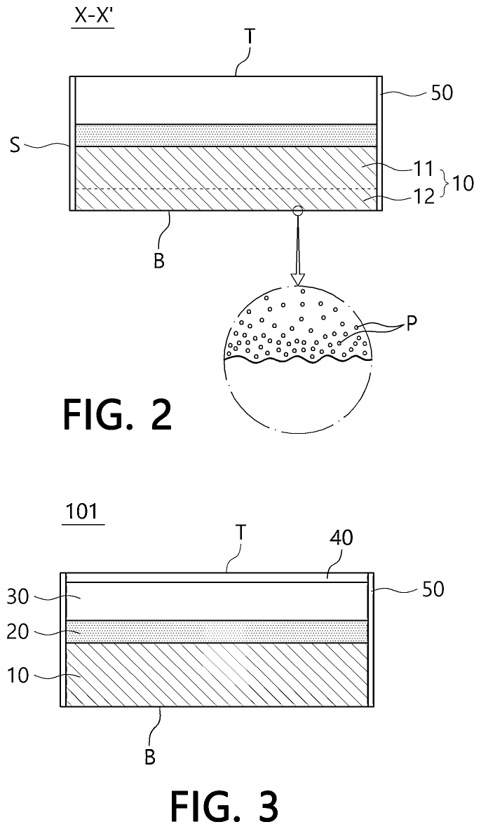

For example, as shown in FIG. 2, the ultra-thin fin LED device 100 may have a structure containing a plurality of pores (P) in a region 12 extending from the first surface (B) of the first conductive semiconductor layer 10 to a predetermined thickness, wherein the structure containing the plurality of pores (P) further lowers the dielectric characteristics and electrical conductivity due to the air contained in the pores (P). Therefore, its material and structure may be different from those of the second conductive semiconductor layer 30 corresponding to the uppermost layer having the second surface (T). In addition, the structure containing the plurality of pores (P) has the advantage of increasing the luminous efficiency by preventing the light emitted from the inside of the ultra-thin fin LED device 100 from being trapped and unable to escape due to internal reflection. On the other hand, the structure containing the plurality of pores (P) may be formed in the n-type GaN portion which is etched through the LED wafer to a partial thickness of the n-type GaN semiconductor in the shape and size of the ultra-thin pin LED device, and then exposed to an etching solution after electrochemical etching treatment to separate the etched LED structure from the LED wafer. In relation to this ultra-thin pin LED structure 100, reference may be made to Korean Patent Application No. 10-2020-0189204 of the present inventors, which is incorporated herein by reference. Meanwhile, for example, the pores may have a diameter of 1 to 100 nm.

Alternatively, according to another embodiment of the present invention, the lowermost layer having the first surface (B) and the uppermost layer having the second surface (T) may be made of materials that differ in at least one of electrical conductivity and dielectric constant from each other. Preferably, they may differ in the electrical conductivity, and for example, the electrical conductivity of the uppermost layer having the second surface (T) may be greater than that of the lowermost layer having the first surface (B). More preferably, the electrical conductivity of the uppermost layer may be 10 times or more, more preferably 100 times or more of that of the lowermost layer, whereby it may be advantageous to achieve a further increased selective mounting ratio.

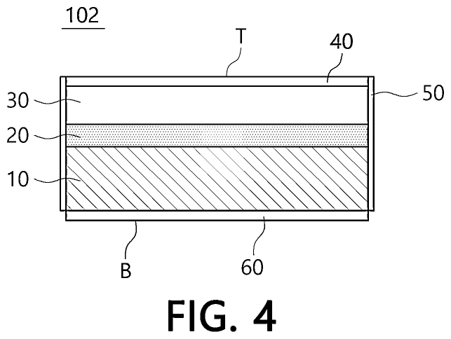

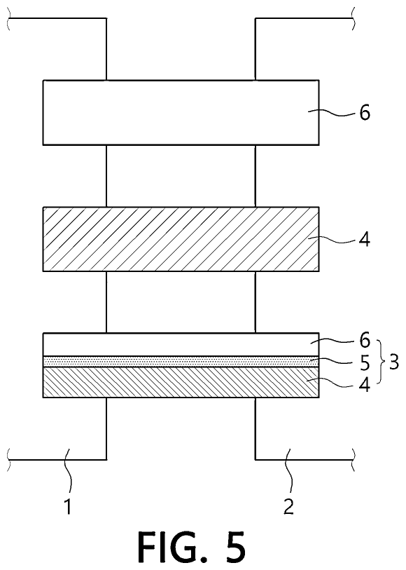

Referring to FIGS. 3 and 4, for example, the ultra-thin pin LED devices 101 and 102 may include, in addition to the first conductive semiconductor layer 10, the photoactive layer 20 and the second conductive semiconductor layer 30, a selective alignment-directing layer 40 or a selective alignment-retarding layer 60 above or below the second conductive semiconductor layer 30 or the first conductive semiconductor layer 10 to provide them as the uppermost layer having the second surface (T) of the ultra-thin pin LED devices 101 and 102 or the lowermost layer having the first surface (B).

The selective alignment-directing layer 40 may be made of a material having higher electrical conductivity than that of the first conductive semiconductor layer 10, and may be an electrode layer as a specific example. As the electrode layer, any conventional electrode layer provided in an LED device may be used without limitation, and as non-limiting examples, Cr, Ti, Al, Au, Ni, ZnO, AZO, ITO, and oxides or alloys thereof may be used alone or in combination. Preferably, in order to increase the selective mounting ratio in which the second surface (T) contacts the upper surface of the mounting electrode compared to other electrode layer materials, the electrical conductivity of the selective alignment-directing layer 40 may be 10 times or more, more preferably 100 times or more, of that of the first conductive semiconductor layer 10, whereby, it may be advantageous to achieve a further increased selective mounting ratio. In addition, when the selective alignment-directing layer 40 is an electrode layer, the thickness may be 10 to 500 nm, but is not limited thereto.

Alternatively, the selective alignment-retarding layer 60 may be made of a material having lower electrical conductivity than that of the second conductive semiconductor layer and may be, for example, an electronic delay layer having an electronic delay function. That is, as the ultra-thin fin LED device is implemented such that the thickness in the stacking direction of each layer is smaller than the length thereof, the thickness of the n-type GaN layer is bound to be relatively thin. In contrast, since the movement speed of electrons is greater than that of holes, the coupling position of the electrons and the holes may be made in the second conductive semiconductor layer 30 rather than in the photoactive layer 20, thereby reducing luminous efficiency. The selective alignment-retarding layer 60, which is the electron delay layer, balances the number of recombined holes and electrons in the photoactive layer 20, thereby increasing the probability that the second surface (T) among several surfaces selectively contacts the mounting electrode while preventing a decrease in luminous efficiency. Preferably, the electrical conductivity of the uppermost layer, for example, the second conductive semiconductor layer 30, may be 10 times or more, more preferably 100 times or more, of that of the selective alignment-retarding layer 60, whereby it may be advantageous to further improve the selective mounting ratio in which the second conductive semiconductor layer 30 contacts the upper surface of the mounting electrode.

The selective alignment-retarding layer 60 may contain, for example, at least one selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, Si, polyparaphenylene vinylene and its derivatives, polyaniline, poly(3-alkylthiophene), and poly(paraphenylene). Alternatively, when the selective alignment-retarding layer 60 is an n-type III-nitride semiconductor layer doped with the first conductive semiconductor layer 10, it may be composed of a III-nitride semiconductor having a lower doping concentration than that of the first conductive semiconductor layer 10. In addition, the thickness of the selective alignment-retarding layer 60 may be 1 to 100 nm, but is not limited thereto, and may be appropriately changed in consideration of the material of the n-type conductive semiconductor layer, the material of the electronic delay layer, and the like.

Alternatively, according to another embodiment of the present invention, in order to generate rotational torque (Tₓ) based on an imaginary axis of rotation passing through the center of the device in the x-axis direction under an electric field, the device may further include a rotation induction film 50 surrounding the side surface thereof. More preferably, in order for any specific one of the first surface (B) and the second surface (T), for example, the second surface (T) to be selectively directed toward the mounting electrode, the rotation induction film 50 covering the side surfaces S of the device may be formed of a material that satisfies the real part of the K(ω) value according to Equation 1 greater than 0 and up to 0.72, more preferably greater than 0 and up to 0.62, as calculated in at least a part of the frequency range within the range where the frequency of the power applied in consideration of the permittivity of the solvent is 10 GHz or less, assuming that the particles in Equation 1 above are spherical core-shell particles composed of GaN as the core and the rotation induction film as the shell (see FIGS. 8A to 8D).

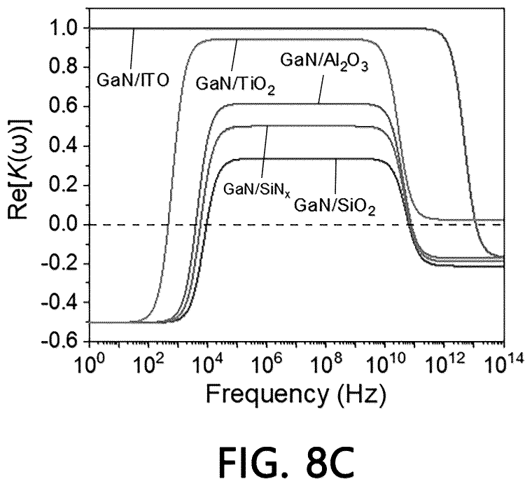

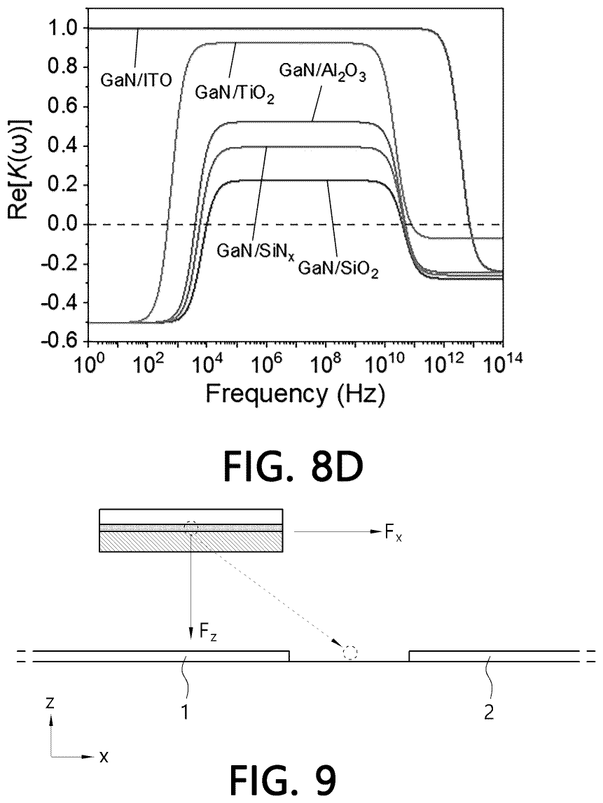

Referring to FIGS. 9 and 10, the ultra-thin pin LED device 3 may have a positive value of Re[K(ω)] in Equation 3 as described above, so that it can be attracted to the high electromagnetic field formed by the power applied to the mounting electrodes 1 and 2. In this case, the rotation induction film 50 generates a rotation torque (T x) based on an imaginary x-axis passing through the center of the ultra-thin pin LED device 3, so that the second surface (T) of the first surface (B) or the second surface (T) can be rotated to face the mounting electrode 1 and 2, thereby increasing the drivable mounting ratio in which the first surface (B) or the second surface (T) of the ultra-thin pin LED device 3 is mounted to contact the upper surface of the mounting electrodes 1 and 2, and further increasing the selective mounting ratio in which a specific one of the first surface (B) and the second surface (T) of the ultra-thin pin LED device 3 is mounted to contact the upper surface of the mounting electrode.

The rotation induction film 50 has a positive number exceeding 0 as the real part of the K(ω) value according to Equation 1 for the spherical core-shell particle in which the lowermost layer having the first surface (B) is a GaN core part and the rotation induction film 50 is disposed as a shell part, and thus, does not hinder the movement of the ultra-thin pin LED devices 100, 101 and 102 being led toward the mounting electrode. Further, the rotation induction film 50 may adopt a material having the value of 0.72 or less, thereby significantly improving the drivable mounting ratio among all ultra-thin pin LED devices put into the mounting electrode, and the selective mounting ratio in which a specific one of the first surface (B) and the second surface (T) is arranged to contact the mounting electrode surface. If the side surfaces of the ultra-thin pin LED device are provided with the rotation induction film 50 having the real part of the K(ω) value according to Equation 1 which is 0 or a negative number or exceeds 0.72, the drivable mounting ratio, and the selective mounting ratio in which a specific one of the first surface (B) and the second surface (T) becomes the mounting surface (or contact surface) are reduced, and in particular, the selective mounting ratio may be greatly reduced (see Table 2).

On the other hand, when the ultra-thin pin LED device has a different electrical conductivity and/or dielectric constant between the lowermost layer having the first surface (B) and the uppermost layer having the second surface (T) due to material and/or structural adjustment while at the same time having the side surfaces provided with the rotation induction film 50 having the real part of the K(ω) value greater than 0 and up to 0.72, the drivable mounting ratio and selective mounting ratio of the devices can be further increased (see Table 2).

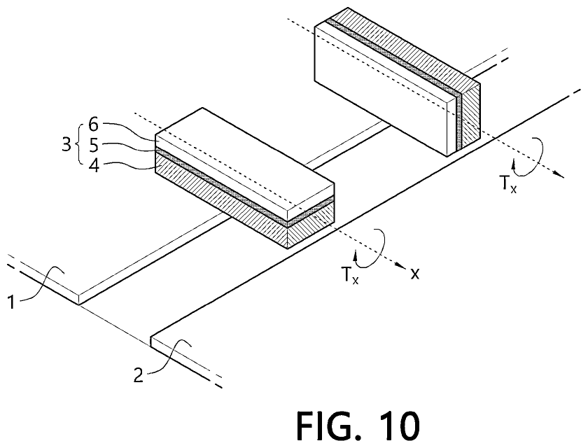

In addition, the rotation induction film 50 satisfying the real part of the K(ω) value according to Equation 1 greater than 0 and up to 0.62 under the same conditions as described above increases the drivable mounting ratio of the ultra-thin pin LED device, and the selective mounting ratio in which a specific one of the first surface (B) and the second surface (T) selectively contacts, while at the same time exhibiting the effect of increasing the good-quality mounting ratio, which is a mounting ratio that can be of good-quality when the driving electrode is formed on the top of the ultra-thin pin LED device arranged through a post-process after being arranged on the mounting electrode. Specifically, referring to FIG. 11, even when the first surface (B) or the second surface (T) is aligned to contact the mounting electrode, the mounting forms may appear as a mounting form according to (a) of FIG. 11A mounted so that each end of the ultra-thin pin LED device is positioned with a similar contact area on the adjacent mounting electrode surface, a mounting form according to FIG. 11(b) mounted so that each end is positioned on the adjacent mounting electrode surface but is biased to one side, or a mounting form according to FIG. 11(c) in which each end is disposed to contact only the surface of one mounting electrodes among the adjacent mounting electrodes. It may be advantageous to have a mounting form as shown in FIGS. 11(a) and 11(b) in order for the driving electrode to be formed while smoothly contacting with the upper surface of the ultra-thin pin LED device. However, in the case of the ultra-thin pin LED device having the rotation induction film 50 whose real part of the K(ω) value deviates from more than 0 and up to 0.62, this is undesirable because the proportion of devices mounted in the form shown in FIG. 11(c) may greatly increase compared to other ultra-thin pin LED devices.

The above-described ultra-thin fin LED devices 100, 101, and 102 according to the present invention can have a more improved emission area by stacking several layers such as the conductive semiconductor layers 10 and 30 and the photoactive layer 20 in the thickness direction and implementing the length longer than the thickness. In addition, even if the area of the photoactive layer 20 exposed as the length increases is slightly increased, since the thickness of the layers to be implemented in the process of manufacturing the ultra-thin pin LED device is thin, the depth to be etched is shallow, whereby eventually defects occurring on the exposed surfaces of the photoactive layer 20 and the conductive semiconductor layers 10 and 30 in the etching process are reduced, which is advantageous for minimizing or preventing a decrease in luminous efficiency due to surface defects.

In addition, the ultra-thin pin LED devices 100, 101 and 102 may have a longer length such that the ratio of the total length to the thickness is, for example, 3:1 or more, more preferably 6:1 or more, which has the advantage of being able to more easily self-align the ultra-thin pin LED device on the mounting electrode by dielectrophoretic force through an electric field. If the ratio of the total length to the thickness of the ultra-thin pin LED device 100 is less than 3:1, it may be difficult to self-align the ultra-thin pin LED device on the mounting electrode by the dielectrophoretic force through the electric field, and the element is not fixed on the electrode, which may lead to an electrical contact short circuit caused by process defects. However, the ratio of the length to the thickness may be 15:1 or less, which can be advantageous in achieving the aspect of the present invention, such as optimization of the turning force that can be self-aligned using an electric field.

Meanwhile, the x-y plane in the ultra-thin pin LED devices 100, 101 and 102 is shown as a rectangle in FIGS. 1 to 4, but is not limited thereto, and it should be noted that any shapes ranging from general rectangular shapes such as rhombus, parallelogram, and trapezoid to elliptical shapes can be employed without limitation.

In addition, the ultra-thin pin LED devices 100, 101, and 102 according to an embodiment of the present invention have a micro or nano size in length and width. For example, the length of the ultra-thin pin LED devices 100, 101 and 102 may be 1 to 10 μm, and the width thereof may be 0.25 to 1.5 μm. In addition, the thickness may be 0.1 to 3 μm. The length and width may have different bases depending on the shapes of the plane, and for example, when the x-y plane is a rhombus or a parallelogram, one of the two diagonals may be the length and the other may be the width, and in the case of a trapezoid, the longer of the height, upper side, and lower side may be the length, and the shorter side perpendicular to the longer side may be the width. Alternatively, when the shape of the plane is an ellipse, the major axis of the ellipse may be the length, and the minor axis may be the width.

In addition, the ultra-thin pin LED device according to an embodiment of the present invention can be implemented such that the width, which is the length in the y-axis direction, is smaller than the thickness, which may be advantageous in preventing electrical short circuit or leakage that may occur due to the ultra-thin pin LED device arranged so that its side surface contacts the mounting electrode. In other words, when an ultra-thin pin LED device is input and aligned on the mounting electrode, the ratio of the device whose side surface contacts the mounting electrode may exceed about 0% even when the above-described preferable conditions are satisfied. However, if the width of the ultra-thin pin LED device is formed smaller than the thickness, a difference in height from the mounting electrode to the top of the element occurs between the drivably mounted ultra-thin pin LED device and the non-drivably mounted ultra-thin pin LED device. Since the height of the non-drivably mounted ultra-thin pin LED device is lower, the non-drivably mounted ultra-thin pin LED device is buried by the insulating layer deposited above the ultra-thin pin LED device mounted by a post-process for forming the driving electrode, and the upper surface is not exposed. Therefore, even when the driving electrode is formed on the top of the formed insulating layer, contact between the driving electrode and the side surface of the non-drivably mounted ultra-thin pin LED device can be prevented, thereby preventing electrical short circuit and leakage.

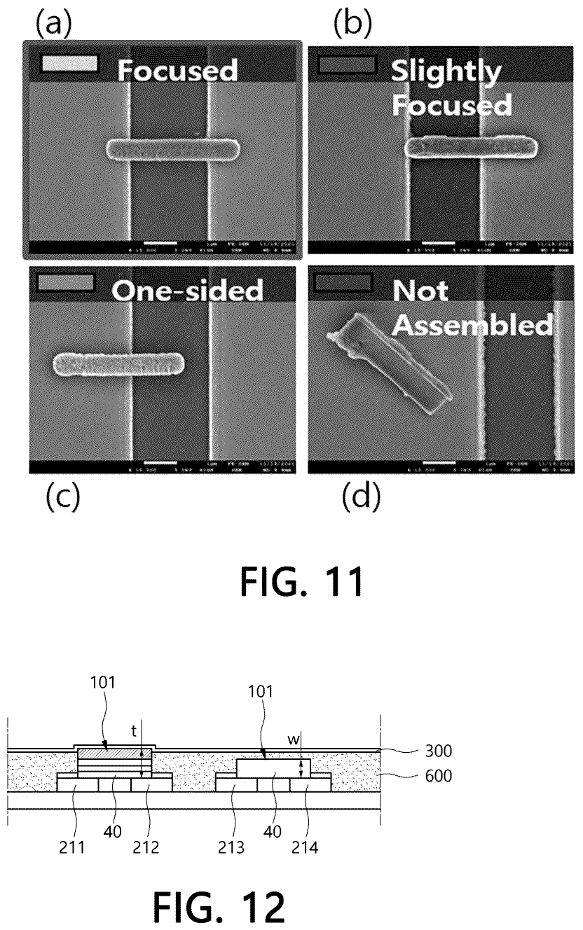

Referring to FIG. 12, the ultra-thin pin LED device 101 in contact with the lower electrodes 213 and 214 located on the right side among the four lower electrodes 211, 212, 213 and 214 is mounted such that the side surfaces of the device are in contact to be non-drivable. In this case, since the width (W) of the ultra-thin pin LED device 101 is smaller than the thickness (t), there is no fear of contacting the upper electrode line 300 formed on the top of the ultra-thin pin LED device. Therefore, when driving power is applied, it is possible to prevent an electrical short circuit or leakage that may occur due to the ultra-thin pin LED device mounted to be non-drivable.

The above-described ultra-thin pin LED devices 100, 101, and 102 according to an embodiment of the present invention can be used for light sources used in various industrial applications, wherein the light sources may be, for example, various LED lights for home/vehicle use, light emitting sources of various displays such as backlight units used in LCDs or light emitting sources of active displays, medical devices, beauty devices, various optical devices, or one part constituting the same. In addition, in the method of implementing the light source, it may be useful for a method of mounting a device on a mounting electrode through dielectrophoresis.

Meanwhile, the ultra-thin pin LED device according to the present invention can be implemented as an ink composition necessary for mass production of a method for mounting the ultra-thin pin LED device on a mounting electrode through dielectrophoresis. The ink composition includes a plurality of the ultra-thin pin LED devices according to an embodiment of the present invention described above in a solvent. As the solvent, any solvent contained in a conventional ink composition may be used without limitation, and may be appropriately selected in consideration of a specifically used printing method and apparatus. In addition, the solvent may have an appropriate dielectric constant so as to have dielectrophoretic force such that the implemented ultra-thin pin LED device is attracted toward the mounting electrode during dielectrophoresis. Preferably, the solvent may have a dielectric constant of 10.0 or more, as another example, 30 or less, and as still another example, 28 or less. For example, such a solvent may be acetone, isopropyl alcohol, or the like. In addition, the ink composition may further include additives that are generally added in consideration of the printing method and apparatus, which are not particularly limited in the present invention.

Hereinafter, the present invention will be described in more detail by way of the following examples, but it should be understood that the examples are not intended to limit the scope of the present invention, but to aid understanding of the present invention.

### Example 1

A conventional LED wafer (Epistar) was prepared in which an undoped n-type III-nitride semiconductor layer, a Si-doped n-type III-nitride semiconductor layer (thickness: 4 μm), a photoactive layer (thickness: 0.15 μm), and a p-type III-nitride semiconductor layer (thickness: 0.05 μm) are sequentially stacked on a substrate. On the prepared LED wafer, ITO (thickness: 0.15 μm) as a selective alignment-directing layer, SiO₂ (thickness: 1.2 μm) as a first mask layer, and Ni (thickness: 80.6 nm) as a second mask layer were sequentially deposited, and then a rectangular pattern-transferred SOG resin layer was transferred onto the second mask layer using nanoimprint equipment. Then, the SOG resin layer was cured using RIE, and the remaining resin portion of the resin layer was etched through RIE to form a resin pattern layer. Thereafter, the second mask layer was etched using ICP along the pattern, and the first mask layer was etched using RIE. Thereafter, the first electrode layer, the p-type III-nitride semiconductor layer, and the photoactive layer were etched using ICP, and then the doped n-type III-nitride semiconductor layer was etched to a thickness of 0.5 μm, and an LED wafer having a plurality of LED structures (long side 4 μm, short side 750 nm, height 850 nm) from which the mask pattern layer was removed by KOH wet etching was manufactured. Afterwards, a temporary protective film of Al₂O₃ was deposited on the LED wafer having the plurality of LED structures formed therein (deposition thickness of 72 nm based on the side surface of the LED structure), and then the temporary protective film material formed between the plurality of LED structures was removed through RIE to expose the top surface of the doped n-type III-nitride semiconductor layer between the LED structures.

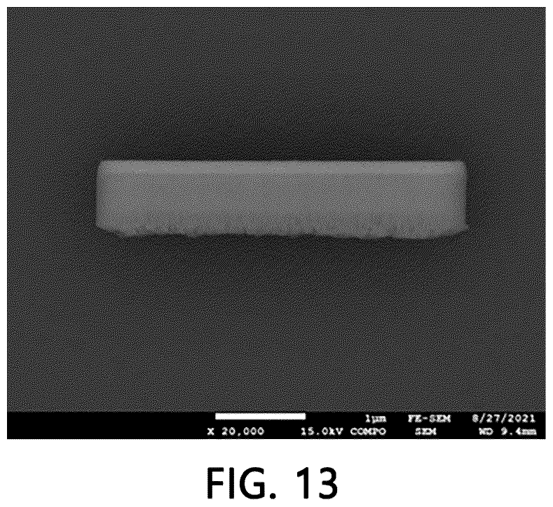

Thereafter, the LED wafer having the temporary protective film formed was immersed in an electrolyte, which is an aqueous solution of 0.3 M oxalic acid, and then connected to an anode terminal of the power supply. A cathode terminal was connected to a platinum electrode immersed in the electrolyte, and then a 15V voltage was applied for 5 minutes to form a plurality of pores in the thickness direction from the surface of the doped n-type III-nitride semiconductor layer between the LED structures. Thereafter, the temporary protective film was removed through ICP, and then a rotation induction film of SiO₂ was deposited with a thickness of 60 nm based on the side surface of the LED structure, wherein the rotation induction film of SiO₂ has a real part of the K(ω) value according to Equation 1 of 0.336 when the solvent is acetone with a dielectric constant of 20.7 and the frequency of the applied power is in the frequency band of 10 kHz to 10 GHz, assuming that the particles in Equation 1 above are spherical core-shell particles having a radius of 430 nm and composed of GaN with a radius of 400 nm as the core part and a rotational induction film with a thickness of 30 nm as the shell part. Thereafter, the rotation induction film material formed between the LED structures is removed through RIE to expose an upper surface of the doped n-type III-nitride semiconductor layer between the LED structures. Then, the LED wafer was immersed in a 100% gamma-butyrolactone bubble-forming solution, and ultrasonic waves were irradiated thereto at an intensity of 160 W and 40 kHz for 10 minutes to generate bubbles. The generated bubbles were used to collapse the pores formed in the doped n-type III-nitride semiconductor layer, thereby manufacturing a plurality of ultra-thin fin LED devices as shown in the SEM picture of FIG. 13.

### Example 2

An ultra-thin pin LED device was manufactured in the same manner as in Example 1, except that the rotation induction film was changed to a rotation induction film of SiNₓ having a value of the real part of K(ω) according to Equation 1 of 0.501 under the same conditions.

### Example 3

An ultra-thin pin LED device was manufactured in the same manner as in Example 1, except that the rotation induction film was changed to a rotation induction film of TiO₂ having a value of the real part of K(ω) according to Equation 1 of 0.944 under the same conditions.

### Example 4

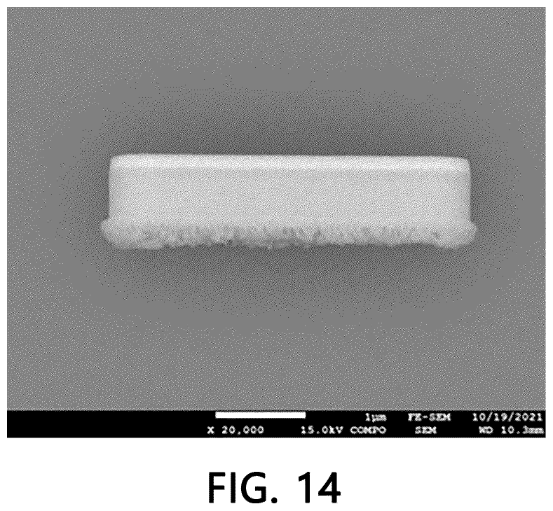

An ultra-thin pin LED device as shown in the SEM picture of FIG. 14 was manufactured in the same manner as in Example 1, except that the rotation induction film was not formed.

### Example 5

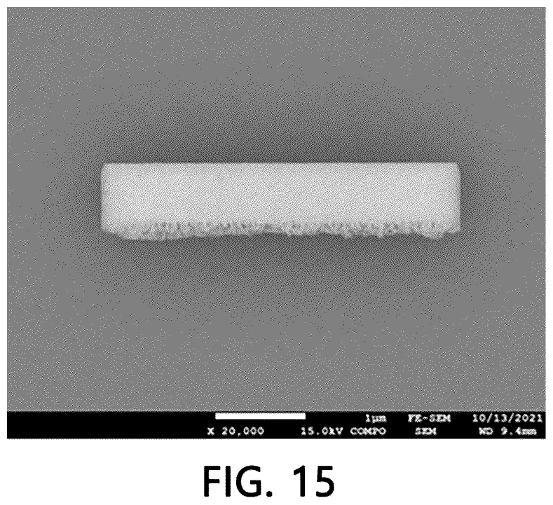

An ultra-thin pin LED device as shown in the SEM picture of FIG. 15 was manufactured in the same manner as in Example 1, except that ITO as a selective alignment-directing layer was not formed.

### Example 6

An ultra-thin pin LED device was manufactured in the same manner as in Example 3, except that ITO as a selective alignment-directing layer was not formed.

### Example 7

An ultra-thin pin LED device was manufactured in the same manner as in Example 1, except that the rotation induction film was deposited without forming a temporary protective film and a plural of pores, and then the rotation induction film material formed on the top of the LED structure was removed through etching, and the LED structure was separated from the wafer using a diamond cutter.

### Example 8

An ultra-thin pin LED device was manufactured in the same manner as in Example 7, except that the rotation induction film was changed to a rotation induction film of Al₂O₃ having a value of the real part of K(ω) according to Equation 1 of 0.616 under the same conditions.

### Example 9

An ultra-thin pin LED device was manufactured in the same manner as in Example 7, except that the rotation induction film was changed to a rotation induction film of TiO₂ having a value of the real part of K(ω) according to Equation 1 of 0.944.

### Example 10

An ultra-thin pin LED device was manufactured in the same manner as in Example 7, except that the rotation induction film was not formed.

### Example 11

An ultra-thin pin LED device was manufactured in the same manner as in Example 7, except that ITO as a selective alignment-directing layer was not formed.

### Example 12

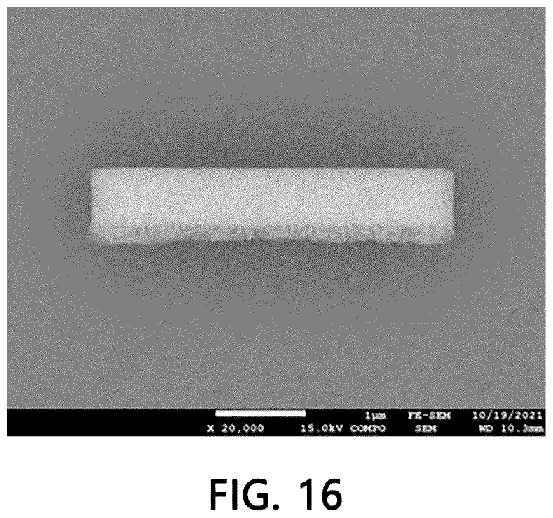

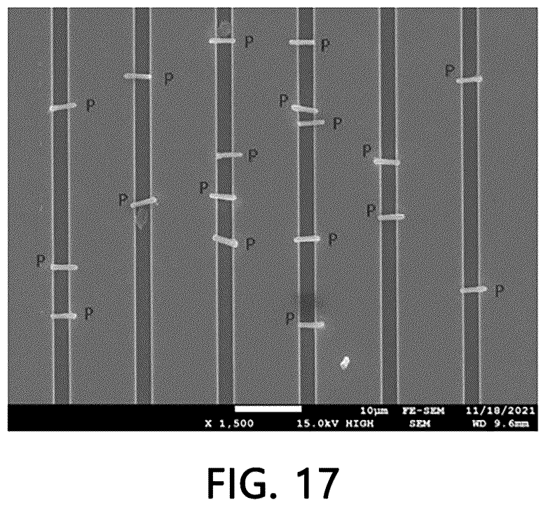

An ultra-thin pin LED device as shown in the SEM picture of FIG. 16 was manufactured in the same manner as in Example 1, except that ITO as a selective alignment-directing layer and a rotation induction film were not formed.

### Comparative Example 1

An ultra-thin pin LED device was manufactured in the same manner as in Example 7, except that ITO as a selective alignment-directing layer and a rotation induction film was not formed.

### Comparative Example 2

A conventional LED wafer (Epistar) was prepared in which an undoped n-type III-nitride semiconductor layer, a Si-doped n-type III-nitride semiconductor layer (thickness: 4 μm), a photoactive layer (thickness: 0.45 μm), and a p-type III-nitride semiconductor layer (thickness: 0.05 μm) are sequentially stacked on a substrate. On the prepared LED wafer, SiO₂ (thickness: 1.2 μm) as a first mask layer, and Ni (thickness: 80.6 nm) as a second mask layer were sequentially deposited, and then an SOG resin layer having a rectangular pattern transferred in the same size as in Example 1 was transferred onto the second mask layer using nanoimprint equipment. Then, the SOG resin layer was cured using RIE, and the remaining resin portion of the resin layer was etched through RIE to form a resin pattern layer. Thereafter, the second mask layer was etched using ICP along the pattern, and the first mask layer was etched using RIE. Thereafter, the first electrode layer, the p-type III-nitride semiconductor layer, and the photoactive layer were etched using ICP, and then the doped n-type III-nitride semiconductor layer was etched to a thickness of 0.6 μm, and then an LED wafer having a plurality of LED structures from which the mask pattern layer was removed by KOH wet etching was manufactured. Afterwards, Al₂O₃ as a temporary protective film was deposited on the LED wafer having the plurality of LED structures formed therein (deposition thickness of 72 nm based on the side surface of the LED structure), and then the temporary protective film material formed between the plurality of LED structures was removed through RIE to expose the top surface of the doped n-type III-nitride semiconductor layer between the LED structures. Thereafter, the doped n-type III-nitride semiconductor layer between the LED structures was further etched to a thickness of 0.2 μm to expose the doped n-type III-nitride semiconductor layer without the temporary protective film formed on the side surface. Then, the doped n-type III-nitride semiconductor layer exposed on the side surface of the LED structure was etched using ICP so that the doped n-type III-nitride semiconductor layer was etched in the width direction from both sides to the center. Afterwards, the temporary protective film formed on the side surface of each LED structure was removed through RIE, and a plurality of LED structures were separated by applying ultrasonic waves to the wafer. The separated LED structure was implemented to have a protrusion extending in the longitudinal direction with a predetermined width and protruding in the thickness direction on the lower surface of the doped n-type III-nitride semiconductor layer due to etching in the width direction. In this case, the ultra-thin pin LED device was manufactured so that the height from the p-type III-nitride semiconductor layer to the protrusion, and the length and width of the device were identical to those of the ultra-thin device in Example 1.

### Experimental Example 1

A mounting electrode line was prepared in which a first mounting electrode and a second mounting electrode extending in a first direction are alternately formed on a base substrate made of quartz and having a thickness of 500 μm so that the interval is 3 μm in a second direction perpendicular to the first direction. Here, the first mounting electrode and the second mounting electrode each have a width of 10 μm and a thickness of 0.2 μm, the material of the first mounting electrode and the second mounting electrode is gold, and the area of the region of the mounting electrode line on which the ultra-thin pin LED device is mounted was 1 mm². In addition, an insulating partition made of SiO₂ was formed on the base substrate to a height of 0.5 μm to surround the region.

Thereafter, 120 ultra-thin fin LED devices are mixed with acetone having a dielectric constant of 20.7 to prepare a solution. 9 μl of the prepared solution was dropped twice in the region, and then a sine wave AC power of 10 kHz and 40 Vpp was applied to the first mounting electrode and the second mounting electrode to mount the ultra-thin pin LED device on the mounting electrode through dielectrophoresis.

1. Mounting Surface Analysis

SEM pictures were taken, and the mounting surface of each of the ultra-thin pin LED devices in contact with the upper surface of the mounting electrode on the above region was observed and counted. The results are shown in Table 2 below as a percentage of the number of ultra-thin pin LED devices input.

In addition, the table also shows the drivable mounting ratio in which the mounting surface of the ultra-thin pin LED device is the first surface (B) or the second surface (T), and the selective mounting ratio in which a specific one of the first surface (B) and the second surface (T) becomes the mounting surface for each example or comparative example.

TABLE 2

| | Ultra-thin pin LED | | | | | | | | |
|---|---|---|---|---|---|---|---|---|---|
| | device | | | Mounting surface of ultra-thin | | | | Mounting ratio | |
| | | | Rotation | pin LED device | | | | | Selective |
| | First | Second | induction | Second | | First | | | mounting |
| | surface | surface | film | surface | Side | surface | | Drivable | (ratio/ |
| | (B) | (T) | (K(ω)) | (T) | surface | (B) | Total | mounting | surface) |
| Example 1 | Pore/N | Selective | SiO₂/ | 94% | 6% | 0% | 100% | 94% | 94%/Second |
| | | alignment- | 0.336 | | | | | | surface |
| Example 2 | Pore/N | directing | SiNₓ/ | 94% | 4% | 2% | 100% | 96% | 94%/Second |
| | | layer | 0.501 | | | | | | surface |
| Example 3 | Pore/N | (ITO) | TiO₂/ | 54% | 25% | 21% | 100% | 75% | 54%/Second |
| | | | 0.944 | | | | | | surface |
| Example 4 | Pore/N | | None | 88% | 7% | 5% | 100% | 93% | 88%/Second |
| | | | | | | | | | surface |
| Example 5 | Pore/N | P | SiO₂/ | 12% | 17% | 71% | 100% | 83% | 71%/First |
| | | | 0.336 | | | | | | surface |
| Example 6 | Pore/N | P | TiO₂/ | 14% | 30% | 56% | 100% | 70% | 56%/First |
| | | | 0.944 | | | | | | surface |
| Example 7 | Non- | Selective | SiO₂/ | 93% | 6% | 1% | 100% | 94% | 93%/Second |
| | pore/N | alignment- | 0.336 | | | | | | surface |
| Example 8 | Non- | directing | Al₂O₃/ | 88% | 12% | 0% | 100% | 88% | 88%/Second |
| | pore/N | layer | 0.616 | | | | | | surface |
| Example 9 | Non- | (ITO) | TiO₂/ | 53% | 25% | 22% | 100% | 75% | 53%/Second |
| | pore/N | | 0.944 | | | | | | surface |
| Example 10 | Non- | | None | 87% | 9% | 4% | 100% | 91% | 87%/Second |
| | pore/N | | | | | | | | surface |
| Example 11 | Non- | P | SiO₂/ | 11% | 17% | 72% | 100% | 83% | 72%/First |
| | pore/N | | 0.336 | | | | | | surface |
| Example 12 | Pore/N | P | None | 11% | 44% | 45% | 100% | 56% | 45%/First |
| | | | | | | | | | surface |
| Comparative | Non- | P | None | 3% | 52% | 45% | 100% | 48% | —/Side |
| Example 1 | pore/N | | | | | | | | surface |
| Comparative | Protruded | P | None | 7% | 57% | 36% | 100% | 43% | —/Side |
| Example 2 | structure/N | | | | | | | | surface |

※ In Table 2, N refers to an n-type III-nitride semiconductor layer, and P refers to a p-type III-nitride semiconductor layer.

As can be seen from Table 2, in the ultra-thin pin LED devices according to Comparative Examples 1 and 2, the ratio of drivably mounted devices among all the ultra-thin pin LED devices input is less than 50%, and thus, the ratio of the first surface (B) or the second surface (T) in contact with the upper surface of the mounting electrode is small, whereas in the ultra-thin pin LED devices according to the examples, the ratio of drivably mounted devices among all the ultra-thin pin LED devices input is 56% or more, and thus, it can be seen that the first surface (B) or the second surface (T) dominantly contacts the upper surface of the mounting electrode.

### Experimental Example 2

The ultra-thin pin LED devices according to Examples 1 to 3 were mounted on the mounting electrode line in the same manner as in Experimental Example 1, except that dielectrophoresis was performed by changing the applied power condition to 10 kHz and 20 Vpp. Thereafter, the mounted form of the ultra-thin pin LED device was analyzed based on FIG. 12, and the results are shown in Table 3 below.

TABLE 3

| | Ultra-thin pin LED device | | | Mounting ratio | | Mounting form of drivable | | |
|---|---|---|---|---|---|---|---|---|
| | | | Rotation | (%) | | mounting (%) | | |
| | First | Second | induction | | Side | Equal | Biased | |
| | surface | surface | film | Drivable | surface | both ends | both ends | One end |
| | (B) | (T) | (K(ω)) | mounting | mounting | mounting | mounting | mounting |
| Example 1 | Pore/N | Selective | SiO₂/ | 99 | 1 | 46 | 52 | 1 |
| | | alignment- | 0.336 | | | | | |
| Example 2 | Pore/N | directing | SiNₓ/ | 99 | 1 | 37 | 61 | 1 |
| | | layer | 0.501 | | | | | |
| Example 3 | Pore/N | (ITO) | TiO₂/ | 88 | 12 | 36 | 41 | 11 |
| | | | 0.944 | | | | | |

As can be seen from Table 3, in the case of Examples 1 and 2 including the rotation induction film having a real value of K(ω) of 0.6 or less, the ratio of mounting in a form in which both ends are mounted on two adjacent mounting electrodes is similar to that of Example 3 is significantly higher than that of Example 3. Therefore, it can be expected that examples 1 and 2 have a more advantageous mounting form compared to example 3 in forming a new driving electrode on the top of the ultra-thin pin LED device.

Although an embodiment of the present invention have been described above, the spirit of the present invention is not limited to the embodiment presented in the subject specification; and those skilled in the art who understands the spirit of the present invention will be able to easily suggest other embodiments through addition, changes, elimination, and the like of elements without departing from the scope of the same spirit, and such other embodiments will also fall within the scope of the present invention.

What is claimed is:

1. An ultra-thin pin LED device, comprising:
a plurality of layers, and based on mutually perpendicular x-axis, y-axis and z-axis wherein the x-axis direction is a major axis and the layers are stacked in the z-axis direction, a first surface and a second surface opposite to each other in the z-axis direction, and other side surfaces,
wherein as the device in a solvent is attracted by dielectrophoretic force toward a mounting electrode where power is applied and an electric field is formed, the first or second surfaces among the various surfaces of the device are configured to contact an upper surface of the mounting electrode more dominantly than the side surfaces.

2. The ultra-thin pin LED device according to claim 1, wherein the device is configured such that a drivable mounting ratio in which the first surface or the second surface of each element is mounted to come into contact with the upper surface of the mounting electrode satisfies 55% or more based on 120 devices under 10 kHz and 40 Vpp power conditions.

3. The ultra-thin pin LED device according to claim 1, wherein the device is configured such that a selective mounting ratio in which any one of the first and second surfaces is mounted to come into contact with the upper surface of the mounting electrode satisfies 70% or more based on 120 devices under 10 kHz and 40 Vpp power conditions.

4. The ultra-thin pin LED device according to claim 1, wherein the lowermost layer having the first surface has a structure containing a plurality of pores in a region ranging from the first surface to a predetermined thickness.

5. The ultra-thin pin LED device according to claim 1, wherein the uppermost layer having the second surface has a higher electrical conductivity than the lowermost layer having the first surface.

6. The ultra-thin pin LED device according to claim 5, wherein the electrical conductivity of the uppermost layer is 10 times or more than that of the lowermost layer.

7. The ultra-thin pin LED device according to claim 1, wherein in order to generate rotational torque based on an imaginary rotation axis passing through the center of the device in the x-axis direction under an electric field, the device further include a rotation induction film surrounding the side surface of the device.

8. The ultra-thin pin LED device according to claim 7, wherein the rotation induction film has a real part of a K(ω) value according to Equation 1 below that satisfies more than 0 and up to 0.72 in at least a part of frequency range within a frequency range of 10 GHz or less:
$$K ( ω ) = \frac{{ε}_{p}^{*} - {ε}_{m}^{*}}{{ε}_{p}^{*} + 2 {ε}_{m}^{*}} \qquad [ Equation 1 ]$$
wherein K(ω) is an equation between εₚ*, the complex permittivity of the spherical core-shell particle composed of GaN as a core part and a rotation induction film as a shell part, and εₘ*, the complex permittivity of the solvent at an angular frequency ω, wherein the εp* is according to Equation 2 below:
$${ε}_{p}^{*} = {ε}_{2}^{*} \frac{{( \frac{{R}_{2}}{{R}_{1}} )}^{3} + 2 ( \frac{{ε}_{1}^{*} - {ε}_{2}^{*}}{{ε}_{1}^{*} + 2 {ε}_{2}^{*}} )}{{( \frac{{R}_{2}}{{R}_{1}} )}^{3} - ( \frac{{ε}_{1}^{*} - {ε}_{2}^{*}}{{ε}_{1}^{*} + 2 {ε}_{2}^{*}} )} \qquad [ Equation 2 ]$$
wherein R₁ is a radius of the core part, R₂ is a radius of the core-shell particle, and ε₁* and ε₂* are the complex permittivity of the core part and the shell part, respectively.

9. The ultra-thin pin LED device according to claim 1, wherein the plurality of layers include an n-type conductive semiconductor layer, a photoactive layer, and a p-type conductive semiconductor layer.

10. The ultra-thin pin LED device according to claim 1, wherein the thickness, which is a distance in the z-axis direction, is 0.1 to 3 μm, and the length in the x-axis direction is 1 to 10 μm.

11. The ultra-thin pin LED device according to claim 1, wherein the width of the ultra-thin pin LED device, which is the length in the y-axis direction, is smaller than the thickness, which is the length in the z-axis direction.

12. The ultra-thin pin LED device according to claim 7, wherein the rotation induction film has a real part of a K(ω) value according to Equation 1 more than 0 and up to 0.62 in the above frequency range.

13. An ink composition comprising: a plurality of the ultra-thin pin LED devices according to claim 1 and a solvent.
